(19) United States
(12) Patent Application Publication
(10) Pub. No.: US 2026/0060038 A1
(43) Pub. Date: Feb. 26, 2026

(54) APPARATUS AND METHOD FOR MANUFACTURING DISPLAY APPARATUS

(71) Applicant: Samsung Display Co., Ltd., Yongin-si (KR)

(72) Inventors: Myungkyu Kim, Yongin-si (KR); Kyunghoon Chung, Yongin-si (KR); Hyeonsik Kim, Yongin-si (KR); Yong Yeo, Yongin-si (KR); Yongsic Jeon, Yongin-si (KR)

(73) Assignee: Samsung Display Co., Ltd., Yongin-si (KR)

(21) Appl. No.: 19/198,579

(22) Filed: May 5, 2025

(30) Foreign Application Priority Data
Aug. 21, 2024 (KR) 10-2024-0112335

(51) Int. Cl. H01L 21/687; H10K 59/12; H10K 71/16

(52) U.S. Cl. CPC H01L 21/68785; H10K 59/1201; H10K 71/166

(57) ABSTRACT

Provided are an apparatus and method for manufacturing a display apparatus. The apparatus includes a mask frame including an opening area in a central portion of the mask frame, a mask sheet disposed on the mask frame to cover the opening area, a chuck part disposed to face the mask sheet and fix a display substrate, a gripper disposed between the mask sheet and the chuck part to grip the display substrate and to release gripping in case that the chuck part approaches the display substrate and fixes the display substrate, and a deposition source disposed opposite the chuck part with the mask sheet between the deposition source and the chuck part.

### CROSS-REFERENCE TO RELATED APPLICATION(S)

This application claims priority to and benefits of Korean Patent Application No. 10-2024-0112335 under 35 U.S.C. § 119, filed on Aug. 21, 2024, in the Korean Intellectual Property Office, the entire contents of which are incorporated herein by reference.

### BACKGROUND

### 1. Technical Field

One or more embodiments relate to an apparatus and a method, and more particularly, to an apparatus and method for manufacturing a display apparatus.

### 2. Description of the Related Art

Recently, electronic apparatuses have become widely used. Electronic apparatuses are variously used as mobile electronic apparatuses and fixed electronic apparatuses. To support various functions, an electronic apparatus may include a display apparatus to provide visual information such as images to users.

A display apparatus is an apparatus that visually displays data and is formed by depositing various layers such as an organic layer, a metal layer, and the like. A deposition material may be deposited to form multiple layers of a display apparatus. For example, the deposition material from a deposition source is sprayed and deposited on a substrate through a mask.

The background art described above is technical information possessed by the inventor to derive the disclosure or obtained during a process of deriving the disclosure, and is not necessarily considered to be known art disclosed to the general public prior to filing of the disclosure.

### SUMMARY

To have a substrate be adjacent to a mask, the substrate may be supported and transported by a gripper. For example, because a free area is required for the substrate to be supported by the gripper, a non-display area of the substate may be increased. Because the substrate is mounted on a mask sheet and a mask frame while being supported by the gripper, there is a need to process the mask frame separately to prevent interference between the gripper and the mask frame.

One or more embodiments include an apparatus and a method for manufacturing a display apparatus, with a reduced non-display area of a substrate and an improved process efficiency.

However, such a technical problem is just an example, and the disclosure is not limited thereto.

Additional aspects will be set forth in part in the description which follows and, in part, will be apparent from the description, or may be learned by practice of the embodiments.

According to one or more embodiments, an apparatus for manufacturing a display apparatus may include a mask frame including an opening area in a central portion of the mask frame, a mask sheet disposed on the mask frame to cover the opening area, a chuck part disposed to face the mask sheet and fix a display substrate, a gripper disposed between the mask sheet and the chuck part to grip the display substrate and to release gripping in case that the chuck part approaches the display substrate and fixes the display substrate, and a deposition source disposed opposite the chuck part with the mask sheet between the deposition source and the chuck part.

In an embodiment, the gripper may include a holder supporting a first surface of the display substrate, and a pressing part pressing a second surface of the display substrate to grip the display substrate in cooperation with the holder.

In an embodiment, the holder may rotate around a holder shaft to release support of the display substrate.

In an embodiment, as the holder rotates around the holder shaft, the pressing part may ascend to be spaced apart from the holder.

In an embodiment, the gripper may further include a moving plate which is vertically slidable along a support shaft vertically extending, the moving plate connected to the pressing part, and a link bar including a first end portion connected to the holder shaft and a second end portion connected to the moving plate.

In an embodiment, as the holder rotates around the holder shaft, the link bar may also rotate around the holder shaft to push the moving plate upward to move the moving plate in a sliding manner.

In an embodiment, a second end portion of the link bar may move in a sliding manner on a guide rail disposed under the moving plate.

In an embodiment, the chuck part may fix the display substrate, and move toward the mask frame.

In an embodiment, in case that the chuck part fixes the display substrate, the gripper may release gripping such that a first surface of the display substrate facing the mask sheet may be open.

In an embodiment, in case that the chuck part on which the display substrate is fixed moves toward the mask frame and sits on the mask frame, the gripper may not interfere with the mask frame.

In an embodiment, opposite end portions of the mask sheet may be fixed to the mask frame by welding, and a welding line for the welding may have a shape of a straight line.

According to one or more embodiments, a method of manufacturing a display apparatus includes gripping and supporting a display substrate using a gripper such that the display substrate is spaced apart from a mask sheet, moving a chuck part toward the display substrate while the chuck part is spaced apart from the mask sheet and fixing, by the chuck part, the display substrate, releasing, by the gripper, the gripping of the display substrate, and moving the display substrate and the chuck part on which the display substrate is fixed toward the mask sheet, and sitting the display substrate and the chuck part on the mask sheet.

In an embodiment, the gripper may include a holder supporting a first surface of the display substrate, and a pressing part pressing a second surface of the display substrate to grip the display substrate in cooperation with the holder.

In an embodiment, the releasing of the gripping of the display substrate may include rotating the holder around a holder shaft such that the first surface of the display substrate is open.

In an embodiment, the releasing of the gripping of the display substrate may include, as the holder rotates around the holder shaft, raising the pressing part from the second surface of the display substrate such that the pressing part is spaced apart from the holder.

In an embodiment, the gripper may further include a moving plate which is vertically slidable along a support shaft vertically extending, the moving plate connected to the pressing part, and a link bar having a first end portion connected to the holder shaft and a second end portion connected to the moving plate.

In an embodiment, the releasing of the gripping of the display substrate may include, as the holder rotates around the holder shaft, rotating the link bar around the holder shaft, and pushing the moving plate upward.

In an embodiment, in case that the chuck part and the display substrate fixed on the chuck part sit on the mask sheet, the gripper may be spaced apart from the mask sheet and be located above the mask sheet.

In an embodiment, an electronic device may include a display apparatus which includes functional layers to display images, wherein the functional layers are formed through a processing process using the apparatus.

The electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display apparatus, according to an embodiment;

FIG. 2 is a schematic cross-sectional view of a gripper according to an embodiment;

FIG. 3 is a schematic perspective view of a gripper according to an embodiment;

FIGS. 4 to 8 are schematic cross-sectional views showing a method of manufacturing a display apparatus, according to an embodiment;

FIG. 9 is a schematic plan view of a display apparatus manufactured by an apparatus for manufacturing a display apparatus, according to an embodiment;

FIG. 10 is a schematic cross-sectional view, taken along line X-X′ of FIG. 9, of a display apparatus manufactured by an apparatus for manufacturing a display apparatus, according to an embodiment; and

FIGS. 11 and 12 are schematic perspective views illustrating application examples of electronic devices.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. For example, intervening layers, regions, or elements may be present.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element t with other layer, region, or element interposed therebetween.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In an embodiment below, “A and/or B” means A or B, or A and B. For example, “at least one of A and B” means A or B, or A and B.

As used herein, when a wiring is referred to as “extending in a first direction or a second direction”, it means that the wiring not only extends in a straight line shape but also extends in a zigzag or in a curve in the first direction or the second direction.

In an embodiment below, when referring to a “plan view”, it means an object portion is viewed from above. In embodiments below, when referring to a “cross-sectional view”, it means a cross-section of an object portion cut vertically is viewed from a side. As used herein, when it is referred that a first element “overlaps” a second element, the first element is arranged above or below the second element.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

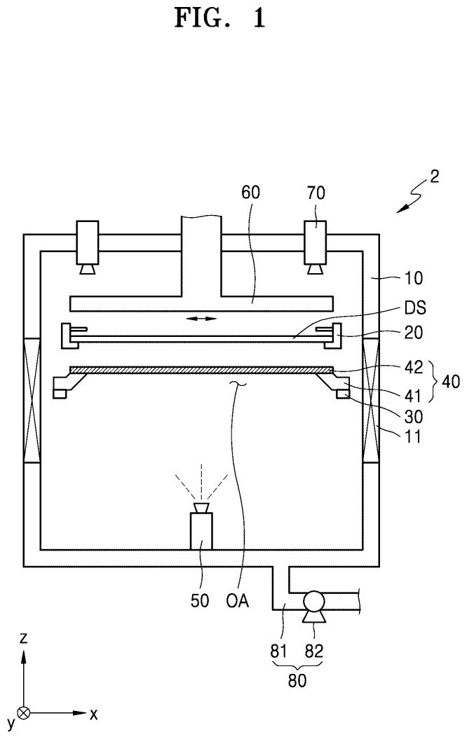

FIG. 1 is a schematic cross-sectional view of an apparatus 2 for manufacturing a display apparatus according to an embodiment.

The apparatus 2 for manufacturing a display apparatus may include a chamber 10, a gripper 20, a supporter 30, a mask assembly 40, a deposition source 50, a chuck part 60, a vision part 70, and a pressure adjustor 80.

A space may be formed inside the chamber 10. A display substrate DS and the mask assembly 40 may be received in the space. For example, a portion of the chamber 10 may be formed to be open. A gate valve 11 may be installed in the open portion of the chamber 10. For example, the open portion of the chamber 10 may be controlled to open or close according to an operation of the gate valve 11.

For example, the display substrate DS may denote a substrate 100 in which at least one of an organic layer, an inorganic layer, and a metal layer is deposited on the substrate 100 described below, while the display apparatus is manufactured. In another example, the display substrate DS may be the substrate 100 on which any of the organic layer, the inorganic layer, and the metal layer is not yet deposited.

The gripper 20 may grip and support the display substrate DS. The gripper 20 may take over the display substrate DS from a transfer unit transferring the display substrate DS into the chamber 10, and grip and support the display substrate DS. The gripper 20 may grip the display substrate DS until the chuck part 60 approaches and chucks and fixes the display substrate DS. The gripper 20 may release the gripping after the display substrate DS is fixed on the chuck part 60.

The supporter 30 may support the mask assembly 40. For example, the supporter 30 may be disposed inside the chamber 10. The supporter 30 may fine-adjust the position of the mask assembly 40. For example, the supporter 30 may include a driver, an alignment unit, or the like separately to move the mask assembly 40 in different directions.

In another embodiment, the supporter 30 may have a shuttle form. For example, the mask assembly 40 may sit (or be disposed) on the supporter 30. The supporter 30 may transfer the mask assembly 40. As an example, the supporter 30 may move to the outside of the chamber 10, and after the mask assembly 40 sits (or is disposed) on the supporter 30, the supporter 30 may enter the chamber 10 from the outside of the chamber 10.

The deposition source 50 may be disposed to face the mask assembly 40. For example, a deposition material may be received in the deposition source 50. The deposition material may be evaporated or sublimated by applying heat to the deposition material. The deposition source 50 may be disposed to be fixed inside the chamber 10, or disposed inside the chamber 10 to be linearly movable in a direction.

The mask assembly 40 may be disposed inside the chamber 10. For example, the mask assembly 40 may include a mask frame 41 and a mask sheet 42. The mask frame 41 may include sides connected to each other and include an opening area OA defined by the sides. For example, the opening area OA may be surrounded by the sides and may pass through the central portion of the mask frame 41. In an embodiment, the mask frame 41 may be a quadrangular frame. However, the shape of the mask frame 41 is not limited thereto but may be various polygonal or circular shapes. Hereinafter, for convenience of description, the case where the mask frame 41 is a quadrangular frame is described.

In the case where the mask frame 41 is a quadrangular frame, the sides may include a first side extending in a first direction (e.g., an x-axis direction in FIG. 1) and a second side extending in a second direction (e.g., a y-axis direction in FIG. 1) intersecting the first direction. Because the first side is provided as a pair to face each other, and the second side is provided as a pair to face each other, the first side may be connected to the second side. In an embodiment, the first side may be a long side, and the second side may be a short side. However, embodiments are not limited thereto and the first side may be a short side, the second side may be a long side, or the first side and the second side may be equal in their lengths. Hereinafter, for convenience of description, the case where the first side is a long side and the second side is a short side is described.

The mask sheet 42 may be tensioned and installed to the mask frame 41. The opening area OA in the central portion of the mask frame 41 may be covered by the mask sheet 42. In an embodiment, at least two mask sheets 42 may be provided. In the case where two or more mask sheets 42 are provided, the mask sheets 42 may be disposed on the mask frame 41 to be parallel to each other. As an example, the mask sheets 42 may respectively extend in the first direction (e.g., the x-axis direction of FIG. 1) and be arranged to be parallel to each other in the second direction (e.g., the y-axis direction of FIG. 1). Two opposite end portions of each of the mask sheets 42 may be fixed to the mask frame 41 by welding.

Each of the mask sheets 42 may include at least one pattern hole. The pattern hole may be a through hole formed to allow the deposition material to pass through the mask sheet 42. The deposition material passing through the mask sheet 42 may be deposited on the display substrate DS.

The chuck part 60 may be disposed inside the chamber 10 to face the display substrate DS and/or the mask assembly 40. The chuck part 60 may be disposed opposite the mask assembly 40 with the display substrate DS between the chuck part 60 and the mask assembly 40. The chuck part 60 may chuck, fix, and maintain the display substrate DS. In an embodiment, the chuck part 60 may include an electrostatic chuck. The electrostatic chuck may fix the display substrate DS to the chuck part 60 using electrostatic force. In another embodiment, the chuck part 60 may include a sticky chuck. The sticky chuck may fix the display substrate DS by bonding the display substrate DS using an adhesive material such as an adhesive pad or adhesive sheet. Hereinafter, for convenience of description, a case where the chuck part 60 includes an electrostatic chuck is described.

The chuck part 60, for example, an electrostatic chuck may have an electrode embedded inside the body, and a power may be applied to the electrode. In case that a high voltage is applied to the electrode, the display substrate DS may be fixed to the surface of the electrostatic chuck. In an embodiment, the chuck part 60 may include an alignment mark for aligning and fixing the display substrate DS. Accordingly, the chuck part 60 and the display substrate DS may be aligned to each other and bonded at an accurate position.

In an embodiment, the chuck part 60 may move vertically (e.g., in a z-axis direction of FIG. 1). The chuck part 60 may move toward the display substrate DS to chuck the display substrate DS gripped by the gripper 20. For example, after chucking the display substrate DS, the chuck part 60 may move toward the mask sheet 42.

The vision part 70 may be disposed in the chamber 10 and may capture the positions of the display substrate DS and the mask assembly 40. For example, the vision part 70 may include a camera capturing the display substrate DS and the mask assembly 40. The positions of the display substrate DS and the mask assembly 40 may be determined based on the images captured by the vision part 70, and the transformation of the mask assembly 40 may be determined. For example, the gripper 20 may fine-adjust the position of the display substrate DS or the supporter 30 may fine-adjust the position of the mask assembly 40 based on the captured images.

The pressure adjustor 80 may be connected to the chamber 10 and may adjust the inner pressure of the chamber 10. As an example, the pressure adjustor 80 may adjust the inner pressure of the chamber 10 to be equal or similar to the atmospheric pressure. For example, the pressure adjustor 80 may adjust the inner pressure of the chamber 10 to be equal or similar to a vacuum state.

The pressure adjustor 80 may include a connection pipe 81 and a pump 82, the connection pipe 81 may be connected to the chamber 10, and the pump 82 may be installed to the connection pipe 81. For example, external air may be introduced through the connection pipe 81 or a gas inside the chamber 10 may be guided to the outside through the connection pipe 81 according to an operation of the pump 82.

A method of manufacturing a display apparatus by using the apparatus 2 for manufacturing a display apparatus, is described. For example, the display substrate DS may be prepared.

The pressure adjustor 80 may maintain the inside of the chamber 10 at a state equal or similar to the atmospheric pressure. The gate valve 11 may operate to open the open portion of the chamber 10.

For example, the display substrate DS may be loaded into the inside of the chamber 10 from the outside. For example, the display substrate DS may be loaded into the chamber 10 in various methods. As an example, the display substrate DS may be loaded into the inside of the chamber 10 from the outside of the chamber 10 by a robot arm disposed outside the chamber 10.

The mask assembly 40 may be disposed inside the chamber 10 as described above. In another embodiment, in the equal or similar manner to the display substrate DS, the mask assembly 40 may be loaded into the inside of the chamber 10 from the outside of the chamber 10.

In case that the display substrate DS is loaded into the chamber 10, the gripper 20 may take over the display substrate DS from a transfer unit such as a robot arm and place the display substrate DS. As an example, the gripper 20 may grip the display substrate DS from the transfer unit and support the display substrate DS. For example, the vision part 70 may capture the positions of the display substrate DS and the mask assembly 40. The positions of the display substrate DS and the mask assembly 40, may be determined based on images captured by the vision part 70. For example, the apparatus 2 for manufacturing a display apparatus may include a separate controller to determine the positions of the display substrate DS and the mask assembly 40.

In case that the determination of the positions of the display substrate DS and the mask assembly 40 is completed, the supporter 30 may fine-adjust the position of the mask assembly 40.

The chuck part 60 may move toward the display substrate DS to chuck and fix the display substrate DS. After the display substrate DS is fixed to the chuck part 60, the gripper 20 may release the gripping and move to be spaced apart from the display substrate DS. Accordingly, the display substrate DS may be fixed by fixing force of the chuck part 60.

The chuck part 60 together with the display substrate DS may move toward the mask assembly 40, for example, the mask sheet 42. The display substrate DS may be fixed to the chuck part 60 and may sit on the mask sheet 42.

For example, the deposition source 50 may operate to supply the deposition material toward the mask assembly 40, and the deposition material passing through pattern holes of the mask sheet 42 may be deposited on the display substrate DS. For example, the deposition source 50 may move in parallel to the display substrate DS and the mask assembly 40, or the display substrate DS and the mask assembly 40 may move in parallel to the deposition source 50. For example, the deposition source 50 may move relative to the display substrate DS and the mask assembly 40. For example, the pump 82 may maintain the pressure of the chamber 10 at a state equal or similar to vacuum by sucking in the gas inside the chamber 10 and discharging the gas to the outside.

As described above, the deposition material supplied from the deposition source 50 may pass through the mask assembly 40, e.g., the mask sheet 42, be deposited on the display substrate DS, and thus, form at least one of a plurality of layers, for example, an organic layer, an inorganic layer, and a metal layer stacked in the display apparatus described below.

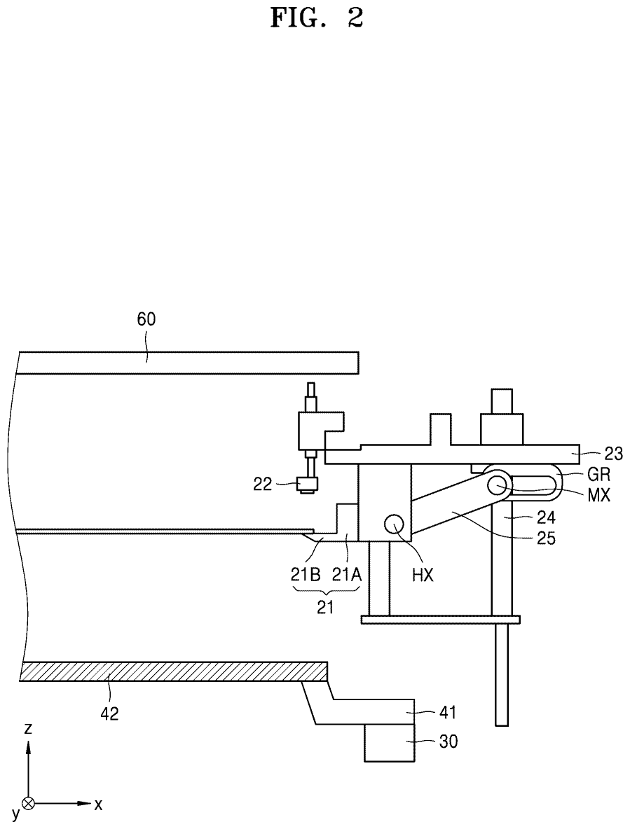

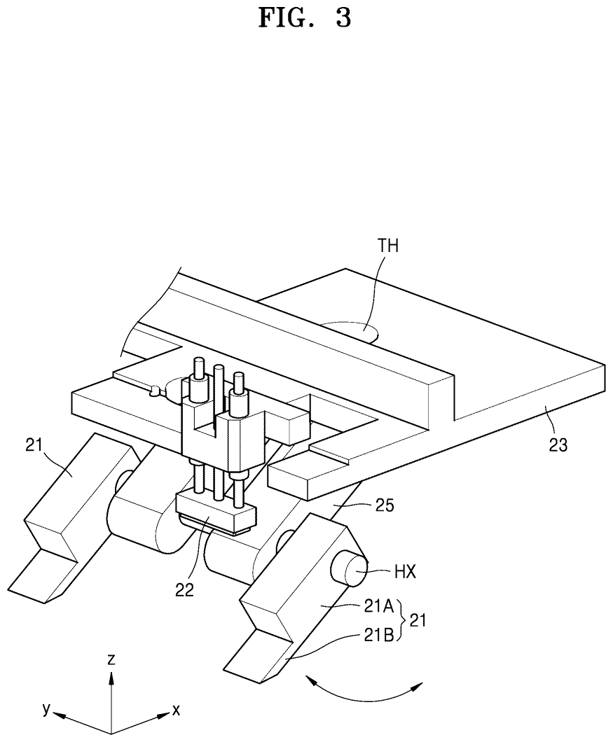

FIG. 2 is a schematic cross-sectional view of the gripper 20 according to an embodiment. FIG. 3 is a schematic perspective view of the gripper 20 according to an embodiment. FIGS. 2 and 3 are enlarged views of a portion of FIG. 1, for example, a right portion, and show the gripper 20.

Referring to FIGS. 2 and 3, in an embodiment, the gripper 20 may include a holder 21, a pressing part 22, a moving plate 23, a support shaft 24, and a link bar 25.

The holder 21 may support the display substrate DS. In an embodiment, the holder 21 may be provided in plurality and disposed on two opposite edges facing the display substrate DS to support the circumference of the display substrate DS. As an example, the holders 21 may be disposed to support an edge portion of the display substrate DS on a side (e.g., a side in a positive x-axis direction) to the first direction and an edge portion of the display substrate DS on another side (e.g., a side in a negative x-axis direction) to the first direction. For example, among the holders, holders 21 for supporting the edge portion of the display substrate DS on a side may be defined as holders in a first group, and holders 21 for supporting the edge portion of the display substrate DS on the another side may be defined as holders in a second group. Hereinafter, for convenience of description, the holders 21 in the first group disposed on a side (in the positive x-axis direction) in the first direction are described as shown in the drawing.

The holders 21 in the first group may be disposed to be spaced apart from each other in the second direction (e.g., the y-axis direction). For example, a holder shaft HX extending in the second direction may pass through the holders 21 in the first group. Accordingly, the holders 21 in the first group may rotate around the holder shaft HX and be rotated in association with each other. For example, as the holder shaft HX rotates, the holders 21 connected to the holder shaft HX may be rotated by the same rotational angle as each other.

In an embodiment, the holder 21 may include a holder body 21A and a holder protrusion 21B. The holder body 21A may be a portion through which the holder shaft HX passes and is inserted, and the holder body 21A may rotate around the holder shaft HX. The holder protrusion 21B may protrude from the holder body 21A and may protrude toward the holders 21 in the second group. The display substrate DS may sit and be supported on the upper surface of the holder protrusion 21B.

The pressing part 22 may press the display substrate DS to grip the display substrate DS in cooperation with the holder 21. In the case where the holder 21 is provided in plurality, the pressing part 22 may be also provided in a number corresponding to the number of holders 21. The holder 21 may support a first surface (e.g., a negative z-axis direction surface) of the display substrate DS, and the pressing part 22 may press a second surface (e.g., a positive z-axis direction surface) of the display substrate DS facing the first surface. Accordingly, the circumference of the display substrate DS may be gripped and fixed by the holder 21 and the pressing part 22.

The pressing part 22 may move in a third direction (e.g., z-axis direction), for example, move vertically. For example, the pressing part 22 may descend to press the display substrate DS and ascend to release the pressing of the display substrate DS. For example, the holder 21 may move in association with the pressing part 22. As an example, in case that the pressing part 22 descends, the holder 21 may rotate clockwise in FIG. 2 to grip the display substrate DS together. For example, in case that the pressing part 22 ascends, the holder 21 may rotate counterclockwise in FIG. 2 to release the gripping of the display substrate DS together. For example, the rotation of the holder 21, and ascending and descending of the pressing part 22 may occur simultaneously in association with each other.

The pressing part 22 may be connected to the moving plate 23. The moving plate 23 may be connected to the pressing part 22 on a side thereof to support the pressing part 22. The moving plate 23 may vertically move, and accordingly, the pressing part 22 may vertically move. In an embodiment, the moving plate 23 may include a through hole TH, and the support shaft 24 may pass through the through hole TH to extend. For example, the support shaft 24 may extend in the third direction, for example, extend vertically, and the support shaft 24 may be disposed to pass through the moving plate 23. The moving plate 23 may vertically move in a sliding manner along the support shaft 24.

The link bar 25 may allow the movements of the holder 21 and the moving plate 23 to be associated with each other. In an embodiment, a first end portion of the link bar 25 may be connected to the holder shaft HX, and a second end portion of the link bar 25 may be connected to the lower portion of the moving plate 23. The first end portion of the link bar 25 may be pierced (or penetrated) and connected to the holder shaft HX. Accordingly, the link bar 25 may rotate as the holder shaft HX rotates. For example, the link bar 25 may rotate together with the holder 21 connected to the holder shaft HX.

In the case where the link bar 25 rotates around the holder shaft HX, the moving plate 23 connected to the second end portion of the link bar 25 may vertically move. As an example, in the case where the holder 21 and the link bar 25 rotate counterclockwise, the link bar 25 may push the moving plate 23 upward to move the moving plate 23 upward. For example, it may be understood that the pressing part 22 connected to the moving plate 23 may move upward. Accordingly, the holder 21 and the pressing part 22 may move to be spaced apart from each other and release the gripping of the display substrate DS. In the case where the holder 21 and the link bar 25 rotate clockwise, the moving plate 23 connected to the link bar 25 may move downward along the link bar 25. For example, it will be understood that the pressing part 22 connected to the moving plate 23 may also move downward. Accordingly, the holder 21 and the pressing part 22 may move to approach each other and grip the display substrate DS.

In an embodiment, the second end portion of the link bar 25 may be connected to be movable in a sliding manner below the moving plate 23. For example, the second end portion of the link bar 25 may be pierced (or penetrated) by a moving shaft MX. The moving shaft MX may extend in the second direction (e.g., the y-axis direction) and extend in parallel to the holder shaft HX. For example, the moving shaft MX may be disposed below the moving plate 23 and disposed on a guide rail GR extending in the first direction (e.g., the positive x-axis direction). Accordingly, the moving shaft MX and the second end portion of the link bar 25 pierced (or penetrated) by the moving shaft MX may move in the first direction in the sliding manner below the moving plate 23. This may facilitate linking the rotation of the link bar 25 to be associated to the vertical movement of the moving plate 23.

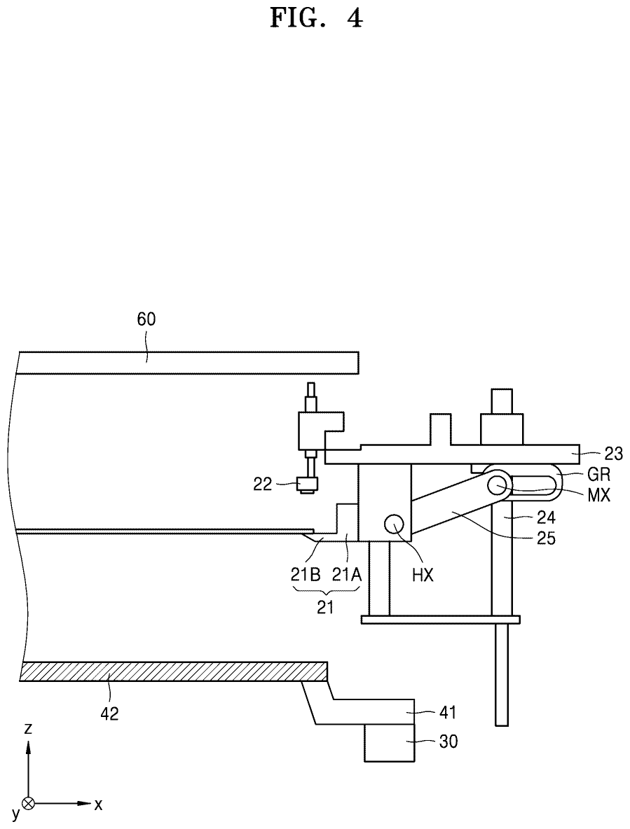

FIGS. 4 to 8 are schematic cross-sectional views showing a method of manufacturing a display apparatus according to an embodiment. FIGS. 4 to 8 show the gripper 20. Although the method of manufacturing a display apparatus may be implemented using the apparatus 2 for manufacturing the display apparatus described above, embodiments are not limited thereto.

Referring to FIG. 4, the display substrate DS loaded by a transfer unit such as a robot arm may be taken over to sit (or be disposed) on the gripper 20, for example, the holder 21. For example, the gripper 20 and the display substrate DS may sit on the gripper 20 may be disposed to be spaced apart from the mask assembly 40 in the third direction (e.g., the positive z-axis direction) and disposed to be spaced apart from the chuck part 60 in the third direction (e.g., the positive z-axis direction). For example, the gripper 20 and the display substrate DS may be disposed between the mask assembly 40 and the chuck part 60.

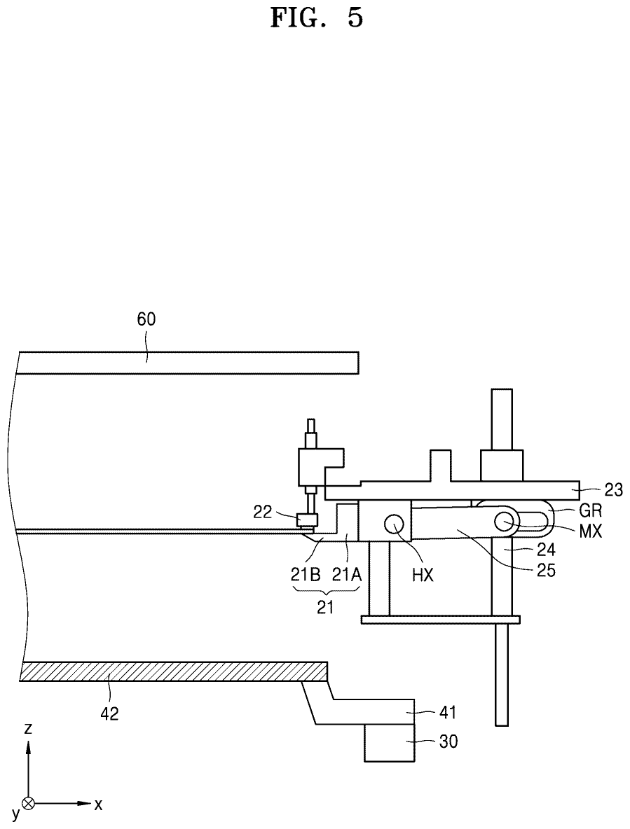

Referring to FIG. 5, as described above, the holders 21 may be disposed to support two opposite edge portions of the display substrate DS facing each other. After the display substrate DS sits on the gripper 20, the pressing part 22 may descend and press the display substrate DS. For example, as described above, it will be understood that, as the pressing part 22 descends (or moves downward), the moving plate 23 connected to the pressing part 22 may also descend (or move downward). The display substrate DS may be gripped and fixed by the holder 21 and the pressing part 22, e.g., the gripper 20.

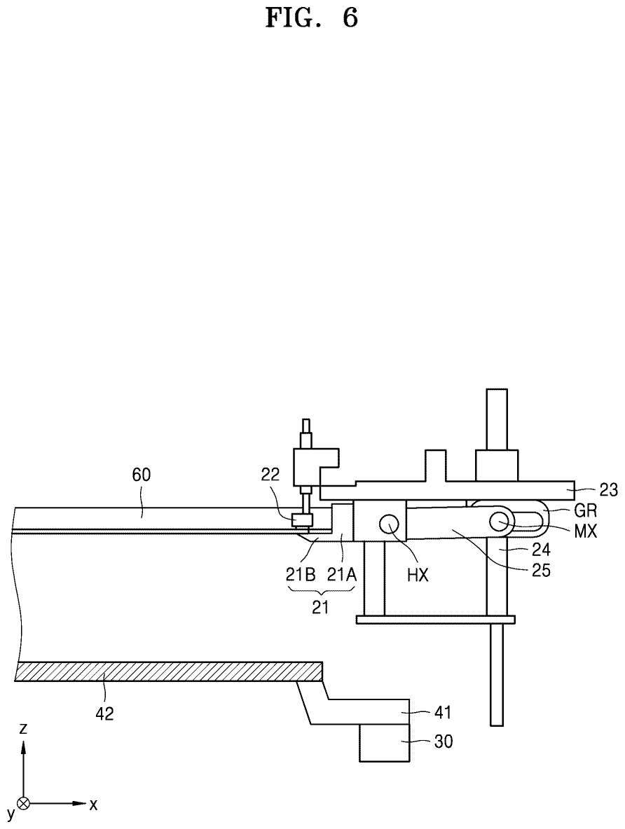

Referring to FIG. 6, the chuck part 60 may move toward the display substrate DS. For example, the chuck part 60 may descend until the chuck part 60 is in contact with the display substrate DS. The chuck part 60 may chuck the display substrate DS, fix and maintain the display substrate DS. In an embodiment, the chuck part 60 may include an electrostatic chuck. The electrostatic chuck may fix the display substrate DS to the chuck part 60 using electrostatic force.

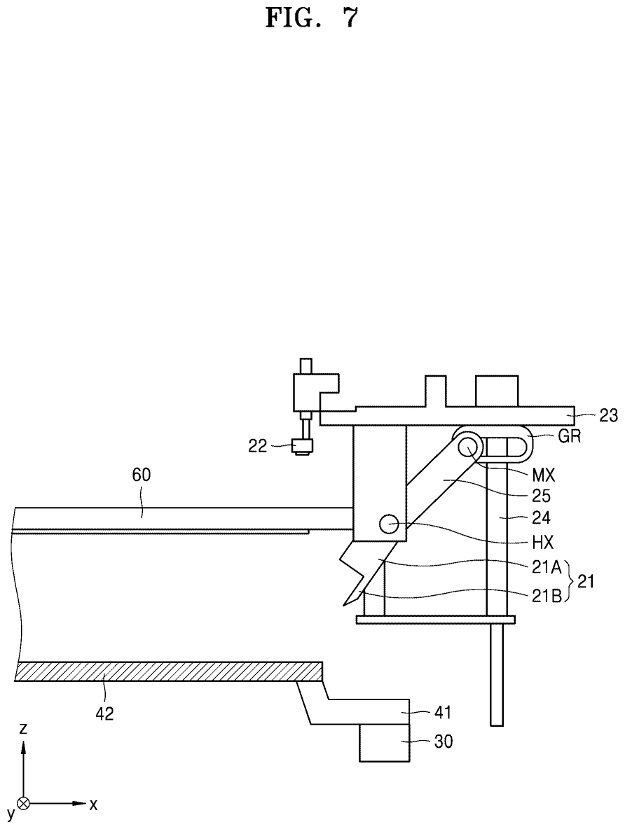

Referring to FIG. 7, after the display substrate DS is fixed to the chuck part 60, the gripper 20 may release the gripping. The holder shaft HX may rotate counterclockwise and the holder 21 may be rotated around the holder shaft HX to open the first surface (e.g., the lower surface) of the display substrate DS. For example, the link bar 25 connected to the holder shaft HX may also rotate around the holder shaft HX, and accordingly, the second end portion of the link bar 25 may ascend. The moving plate 23 may be pushed and raised by the link bar 25. For example, the moving plate 23 may be raised along the support shaft 24 extending vertically. As the moving plate 23 ascends, the pressing part 22 connected to a side of the moving plate 23 may be also raised. Accordingly, the holder 21 may rotate to open the first surface of the display substrate DS, and the pressing part 22 may ascend from the second surface of the display substrate DS to be spaced apart from the holder 21 and may release the gripping of the display substrate DS. For example, the display substrate DS may be fixed to the chuck part 60 by fixing force of the chuck part 60.

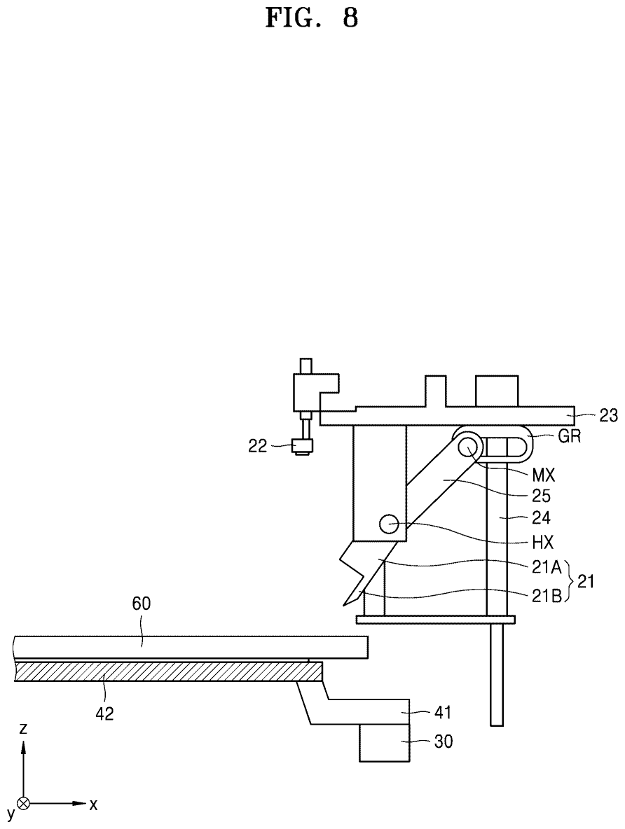

Referring to FIG. 8, the chuck part 60 may fix the display substrate DS thereon and descend toward the mask assembly 40, for example, the mask sheet 42. The chuck part 60 may move such that the display substrate DS may sit on the mask sheet 42. For example, the deposition source 50 may operate to supply the deposition material toward the mask assembly 40, and the deposition material passing through pattern holes of the mask sheet 42 may be deposited on the display substrate DS.

For example, because the display substrate DS is not gripped by the gripper 20, the mask frame 41 and the mask sheet 42 on which the display substrate DS sits may not interfere with the gripper 20. For example, in case that the display substrate DS sits on the mask sheet 42, the gripper 20 supporting the display substrate DS may be released, and the display substrate DS may be fixed by the chuck part 60. Accordingly, a free area, in which the display substrate DS is supported by the gripper 20, may not be required. Accordingly, the area of a non-display area of the display substrate DS may be reduced.

As a comparative example, while the gripper 20, e.g., the holder 21 supports the display substrate DS, the holder 21 may move until the holders 21 sits on the mask frame 41. For example, the display substrate DS may be supported by the gripper 20 that sits on the mask frame 41, an additional area for being supported by the gripper 20 may be required. This may increase the area of the non-display area of the display substrate DS.

For example, in case that the holder 21 sits on the mask frame 41, a groove for sitting the holder 21 may be separately processed in the mask frame 41 to avoid interference. Accordingly, an additional process for manufacturing the groove may be required, and the strength of the mask frame 41 may be deteriorated due to the groove.

For example, in the comparative example, in case that the mask sheet 42 is welded to the mask frame 41, a welding line of the mask sheet 42 may be formed in an uneven shape in a plan view to avoid the groove. For example, in the case where the welding line of the mask sheet 42 is complicated, there may be difficulties in trim processing along the welding line in case of repairing the mask sheet 42.

Unlike the comparative example, according to embodiments, the gripper 20 including the holder 21 may release gripping to open the display substrate DS, and accordingly, the gripper 20 may be spaced apart from the mask assembly 40 and may not sit on the mask sheet 42 in case that the display substrate DS sits on the mask sheet 42. Accordingly, a separate groove may not need to be manufactured in the mask frame 41. Because the groove is not provided, the strength of the mask frame 41 may be maintained.

For example, because the mask frame 41 does not include the groove, the welding line of the mask sheet 42 to the mask frame 41 may be provided in a virtual straight line. This may facilitate trim processing along the welding line in cases of repairing the mask sheet 42. For example, the trim process may be, for example, automated.

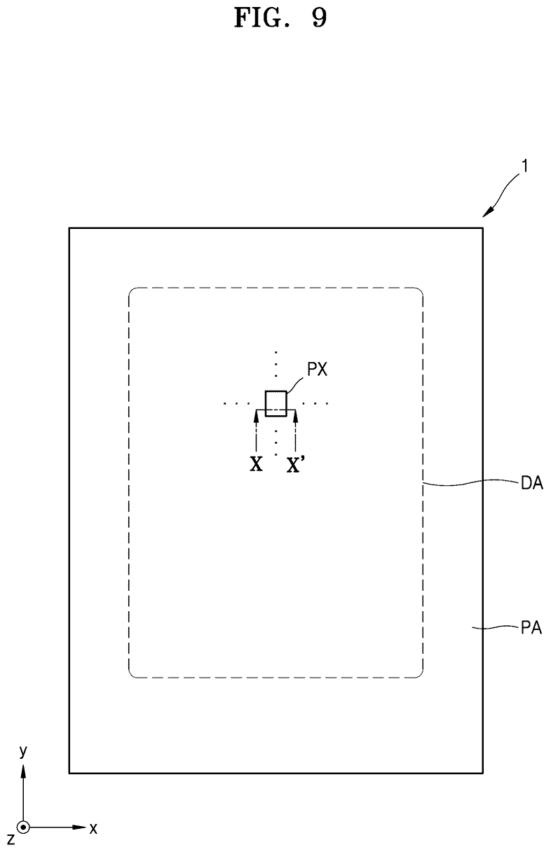

FIG. 9 is a schematic plan view of a display apparatus 1 manufactured by an apparatus for manufacturing the display apparatus 1 according to an embodiment.

Referring to FIG. 9, the display apparatus 1 manufactured according to an embodiment, may include a display area DA and a peripheral area PA outside the display area DA. The display apparatus 1 may display images through an array of pixels PX arranged two-dimensionally in the display area DA.

The peripheral area PA may be a region that does not display images and may surround the display area DA entirely or partially. A driver and the like for providing electrical signals or power to pixel circuits respectively corresponding to the pixels PX may be disposed in the peripheral area PA. A pad may be disposed in the peripheral area PA, and the pad may be a region to which electronic elements or a printed circuit board are electrically connected.

Hereinafter, although the display apparatus 1 includes an organic light-emitting diode OLED as a light-emitting diode, the display apparatus 1 according to an embodiment is not limited thereto. In another embodiment, the display apparatus 1 may be a light-emitting display apparatus including an inorganic light-emitting diode, e.g., an inorganic light-emitting display apparatus. The inorganic light-emitting diode may include a PN diode including inorganic material semiconductor-based materials. In case that a forward voltage is applied to a PN-junction diode, holes and electrons are injected, and light of a preset color may be emitted while energy created by recombination of the holes and the electrons is converted to light energy. The inorganic light-emitting diode may have a width in the range of several micrometers to hundreds of micrometers. In an embodiment, the inorganic light-emitting diode may be denoted by a micro light-emitting diode. In another embodiment, the display apparatus 1 may be a quantum-dot light-emitting display apparatus.

The display apparatus 1 may be used as a display screen in various products including televisions, notebook computers, monitors, advertisement boards, Internet of things (IoTs) apparatuses as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). For example, the display apparatus 1 according to an embodiment may be used in wearable devices including smartwatches, watchphones, glasses-type displays, and head-mounted displays (HMDs). In an embodiment, the display apparatus 1 may be used as a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

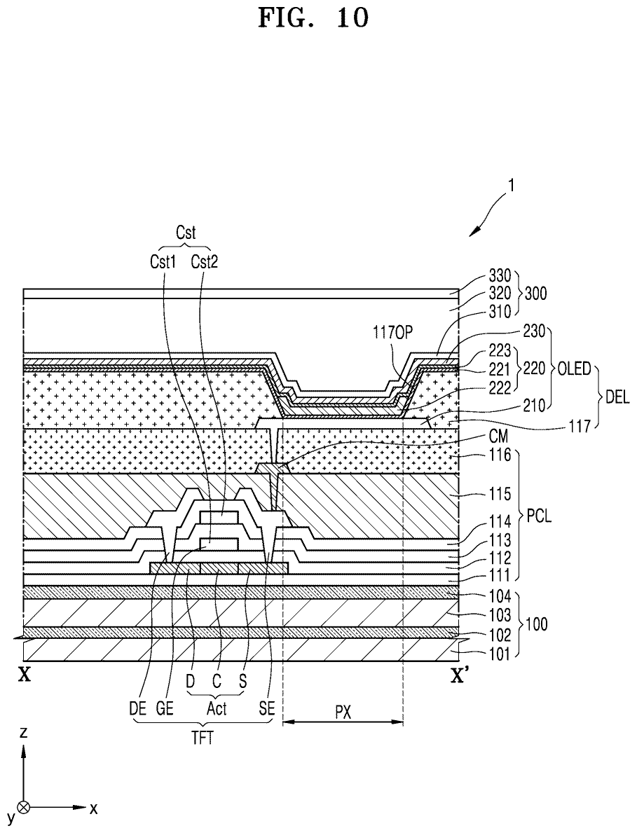

FIG. 10 is a schematic cross-sectional view of the display apparatus 1 manufactured by an apparatus for manufacturing the display apparatus 1 according to an embodiment, taken along line X-X′ of FIG. 9.

Referring to FIG. 10, the display apparatus 1 may include a stack structure of a substrate 100, a pixel circuit layer PCL, a display element layer DEL, and an encapsulation layer 300. The display substrate DS (see FIG. 1) may be a structure in which at least one of, for example, the pixel circuit layer PCL, the display element layer DEL, and the encapsulation layer 300 is stacked on, for example, the substrate 100 during a process of manufacturing the display apparatus 1.

The substrate 100 may have a multi-layered structure including a base layer that includes the polymer resin and an inorganic layer. As an example, the substrate 100 may include the base layer including a polymer resin and a barrier layer including an inorganic insulating layer. As an example, the substrate 100 may include a first base layer 101, a first barrier layer 102, a second base layer 103, and a second barrier layer 104 that are sequentially stacked. The first base layer 101 and the second base layer 103 may each include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose tri acetate (TAC), and/or cellulose acetate propionate (CAP). The first barrier layer 102 and the second barrier layer 104 may each include an inorganic insulating material such as silicon oxide, silicon oxynitride, and/or silicon nitride. The substrate 100 may be flexible.

The pixel circuit layer PCL may be disposed on the substrate 100. It is shown in FIG. 10 that the pixel circuit layer PCL includes a thin-film transistor TFT, a buffer layer 111, a first gate insulating layer 112, a second gate insulating layer 113, an interlayer insulating layer 114, and a first planarization insulating layer 115, and a second planarization insulating layer 116 under and/or on elements of the thin-film transistor TFT.

The buffer layer 111 may reduce or block foreign materials, moisture, or external air penetrating from below the substrate 100 and may provide a flat surface on the substrate 100. The buffer layer 111 may include an inorganic insulating material such as silicon nitride, silicon oxynitride, and silicon oxide, and include a single-layered structure or a multi-layered structure including the above materials.

The thin-film transistor TFT on the buffer layer 111 may include a semiconductor layer Act, and the semiconductor layer Act may include polycrystalline silicon. In another example, the semiconductor layer Act may include amorphous silicon, an oxide semiconductor, or an organic semiconductor. The semiconductor layer Act may include a channel region C, a drain region D, and a source region S respectively arranged on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The first gate insulating layer 112 between the semiconductor layer Act and the gate electrode GE may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

An upper electrode Cst2 of the storage capacitor Cst may be disposed on the second gate insulating layer 113. The upper electrode Cst2 may overlap the gate electrode GE below the upper electrode Cst2. For example, the gate electrode GE and the upper electrode Cst2 overlapping each other with the second gate insulating layer 113 between the gate electrode GE and the upper electrode Cst2, may constitute (or form) the storage capacitor Cst. For example, the gate electrode GE may serve (or function) as a lower electrode Cst1 of the storage capacitor Cst.

As described above, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂). The interlayer insulating layer 114 may include a single layer or a multi-layer including the inorganic insulating material.

A drain electrode DE and a source electrode SE may each be disposed on the interlayer insulating layer 114. The drain electrode DE and the source electrode SE may be respectively connected to the drain region D and the source region S through contact holes of insulating layers below the drain electrode DE and the source electrode SE. The drain electrode DE and the source electrode SE may each include a material having high conductivity. The drain electrode DE and the source electrode SE may each include a conductive material including molybdenum (Mo), aluminum (Al), copper (Cu), and titanium (Ti) and include a single layer or a multi-layer including the above materials. In an embodiment, the drain electrode DE and the source electrode SE may each have a multi-layered structure of Ti/Al/Ti.

The first planarization insulating layer 115 may cover the drain electrode DE and the source electrode SE. The first planarization insulating layer 115 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend (or combination) thereof.

The second planarization insulating layer 116 may be disposed on the first planarization insulating layer 115. The second planarization insulating layer 116 and the first planarization insulating layer 115 may include the same material. The second planarization insulating layer 116 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend (or combination) thereof.

The display element layer DEL may be disposed on the pixel circuit layer PCL having the above structure. The display element layer DEL may include an organic light-emitting diode OLED as a display element (e.g., a light-emitting element). The organic light-emitting diode OLED may have a stack structure of a pixel electrode 210, an intermediate layer 220, and a common electrode 230. The organic light-emitting diode OLED may emit, for example, red light, green light, or blue light, or emit red light, green light, blue light, or white light. The organic light-emitting diode OLED may emit light through an emission area. The emission area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115, and a contact metal CM disposed on the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 210 may further include a layer, which is on/under the reflective layer and includes ITO, IZO, ZnO, or In₂O₃.

A pixel-defining layer 117 may be disposed on the pixel electrode 210, the pixel-defining layer 117 including an opening 117OP exposing a central portion of the pixel electrode 210. The pixel-defining layer 117 may include an organic insulating material and/or an inorganic insulating material. The opening 117OP may define the emission area of light emitted from the organic light-emitting diode OLED. As an example, the size/width of the opening 117OP may correspond to the size/width of the emission area. Accordingly, the size and/or width of the pixel PX may depend on the size and/or width of the opening 117OP of the pixel-defining layer 117.

The intermediate layer 220 may include an emission layer 222 formed to correspond to the pixel electrode 210. The emission layer 222 may include a polymer organic material or a low-molecular weight organic material emitting light having a preset (or certain) color. In another example, the emission layer 222 may include an inorganic emission material or quantum dots.

In an embodiment, the intermediate layer 220 may include a first functional layer 221 and a second functional layer 223 respectively disposed under and on the emission layer 222. The first functional layer 221 may include, for example, a hole transport layer (HTL), or include an HTL and a hole injection layer (HIL). The second functional layer 223 may be an element disposed on the emission layer 222 and may include an electron transport layer (ETL) and/or an electron injection layer (EIL). Like the common electrode 230 described below, the first functional layer 221 and/or the second functional layer 223 may be common layers covering (e.g., entirely covering) the substrate 100.

The common electrode 230 may be disposed on the pixel electrode 210 and may overlap the pixel electrode 210. The common electrode 230 may include a conductive material having a low work function. As an example, the common electrode 230 may include a semi-transparent layer or a transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. In another example, the common electrode 230 may further include a layer, which is on the semi-transparent layer or the transparent layer and includes ITO, IZO, ZnO, or In₂O₃. The common electrode 230 may be formed as a single body to cover the substrate 100 entirely.

The encapsulation layer 300 may be disposed on the display element layer DEL and may cover the display element layer DEL. The encapsulation layer 300 may include at least one inorganic encapsulation layer and at least one organic encapsulation layer. In an embodiment, it is shown in FIG. 10 that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, and polyethylene. In an embodiment, the organic encapsulation layer 320 may include acrylate. The organic encapsulation layer 320 may be formed by hardening a monomer or coating a polymer. The organic encapsulation layer 320 may be transparent.

For example, a touch sensor layer may be disposed on the encapsulation layer 300. An optical functional layer may be disposed on the touch sensor layer. The touch sensor layer may obtain coordinate information corresponding to an external input, for example, a touch event. The optical functional layer may reduce the reflectivity of light (e.g., external light) incident toward the display apparatus 1 from outside, and/or improve the color purity of light emitted from the display apparatus 1. In an embodiment, the optical functional layer may include a phase retarder and/or a polarizer. The phase retarder may include a film-type retarder or a liquid crystal-type retarder. The phase retarder may include a λ/2 phase retarder and/or a λ/4 phase retarder. The polarizer may include a film-type polarizer or a liquid crystal-type polarizer. The film-type polarizer may include a stretchable synthetic resin film, and the liquid crystal-type polarizer may include liquid crystals arranged in a predetermined (or certain) arrangement. Each of the phase retarder and the polarizer may further include a protective film.

An adhesive member may be disposed between the touch sensor layer and the optical functional layer. For the adhesive member, a general adhesive member may be employed without limitation. The adhesive member may be a pressure sensitive adhesive (PSA).

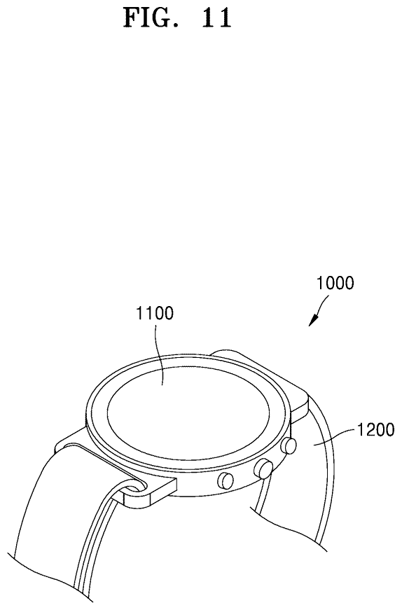

Referring to FIG. 11, the electronic device may be applied to a smart watch 1000 including a display part 1100 and a strap part 1200.

The smart watch 1000 may be a wearable electronic device. For example, the smart watch 1000 may have a structure in which the strap part 1200 is mounted on a wrist of a user. The electronic device may be applied to the display part 1100, so that image data including time information can be provided to the user.

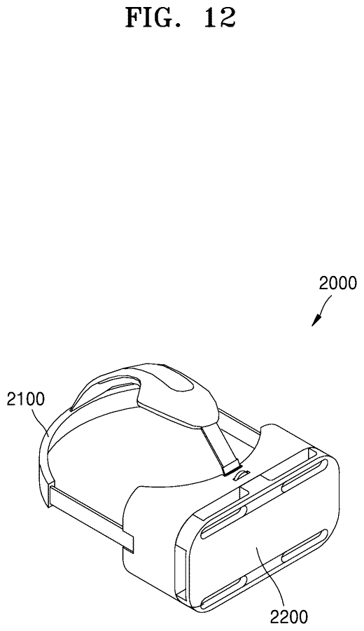

Referring to FIG. 12, the electronic device may be applied to a head mounted display device 2000.

The head mounted display device 2000 may be a wearable electronic device which can be worn on the head of a user. For example, the head mounted display device 2000 may be a wearable device for virtual reality (VR) or mixed reality (MR). The head mounted display device 2000 may include a head mounted band 2100 and a display accommodating case 2200. The head mounted band 2100 may be connected to the display accommodating case 2200. The head mounted band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounted band 2100 may be implemented in the form of a glasses frame, a helmet or the like within the spirit and the scope of the disclosure. For example, the electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

According to embodiments, an apparatus for manufacturing a display apparatus and a method of manufacturing the display apparatus, with a reduced non-display area of a substrate and an improved process efficiency may be provided.

Effects of the disclosure are not limited to the above mentioned effects and other effects not mentioned may be clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display apparatus, the apparatus comprising:
a mask frame including an opening area in a central portion of the mask frame;
a mask sheet disposed on the mask frame to cover the opening area;
a chuck part disposed to face the mask sheet and fix a display substrate;
a gripper disposed between the mask sheet and the chuck part to grip the display substrate and to release gripping in case that the chuck part approaches the display substrate and fixes the display substrate; and
a deposition source disposed opposite the chuck part with the mask sheet between the deposition source and the chuck part.

2. The apparatus of claim 1, wherein the gripper comprises:
a holder supporting a first surface of the display substrate; and
a pressing part pressing a second surface of the display substrate to grip the display substrate in cooperation with the holder.

3. The apparatus of claim 2, wherein the holder rotates around a holder shaft to release support of the display substrate.

4. The apparatus of claim 3, wherein as the holder rotates around the holder shaft, the pressing part ascends to be spaced apart from the holder.

5. The apparatus of claim 3, wherein the gripper further comprises:
a moving plate which is vertically slidable along a support shaft vertically extending, the moving plate connected to the pressing part; and
a link bar including a first end portion connected to the holder shaft and a second end portion connected to the moving plate.

6. The apparatus of claim 5, wherein, as the holder rotates around the holder shaft, the link bar also rotates around the holder shaft to push the moving plate upward to move the moving plate in a sliding manner.

7. The apparatus of claim 6, wherein a second end portion of the link bar moves in a sliding manner on a guide rail disposed under the moving plate.

8. The apparatus of claim 1, wherein the chuck part fixes the display substrate, and moves toward the mask frame.

9. The apparatus of claim 8, wherein, in case that the chuck part fixes the display substrate, the gripper releases gripping such that a first surface of the display substrate facing the mask sheet is open.

10. The apparatus of claim 8, wherein, in case that the chuck part on which the display substrate is fixed moves toward the mask frame and sits on the mask frame, the gripper does not interfere with the mask frame.

11. The apparatus of claim 1, wherein
opposite end portions of the mask sheet are fixed to the mask frame by welding, and
a welding line for the welding has a shape of a straight line.

12. A method of manufacturing a display apparatus, the method comprising:
gripping and supporting a display substrate using a gripper such that the display substrate is spaced apart from a mask sheet;
moving a chuck part toward the display substrate while the chuck part is spaced apart from the mask sheet and fixing, by the chuck part, the display substrate;
releasing, by the gripper, the gripping of the display substrate; and
moving the display substrate and the chuck part on which the display substrate is fixed toward the mask sheet, and sitting the display substrate and the chuck part on the mask sheet.

13. The method of claim 12, wherein the gripper comprises:
a holder supporting a first surface of the display substrate; and
a pressing part pressing a second surface of the display substrate to grip the display substrate in cooperation with the holder.

14. The method of claim 13, wherein the releasing of the gripping of the display substrate comprises rotating the holder around a holder shaft such that the first surface of the display substrate is open.

15. The method of claim 14, wherein the releasing of the gripping of the display substrate comprises, as the holder rotates around the holder shaft, raising the pressing part from the second surface of the display substrate such that the pressing part is spaced apart from the holder.

16. The method of claim 14, wherein the gripper further comprises:
a moving plate which is vertically slidable along a support shaft vertically extending, the moving plate connected to the pressing part; and
a link bar having a first end portion connected to the holder shaft and a second end portion connected to the moving plate.

17. The method of claim 16, wherein the releasing of the gripping of the display substrate comprises, as the holder rotates around the holder shaft, rotating the link bar around the holder shaft, and pushing the moving plate upward.

18. The method of claim 12, wherein, in case that the chuck part and the display substrate fixed on the chuck part sit on the mask sheet, the gripper is spaced apart from the mask sheet and is located above the mask sheet.

19. An electronic device comprising a display apparatus which includes functional layers to display images, wherein the functional layers are formed through a processing process using the apparatus of claim 1.

20. The electronic device of claim 19, wherein the electronic device is at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.
